(19) United States
(12) Patent Application Publication
(10) Pub. No.: US 2006/0030134 A1
(43) Pub. Date: Feb. 9, 2006

(54) Ion sources and ion implanters and methods including the same

(76) Inventors: Yong-Kwon Kim, Gyeonggi-do (KR); Jae-Chul Lee, Gyeonggi-do (KR); Sung-Ho Kang, Gyeonggi-do (KR); Sang-Chul Lee, Gyeonggi-do (KR); Ui-Yong Jeoung, Gyeonggi-do (KR)

Correspondence Address: MYERS BIGEL SIBLEY & SAJOVEC, PO BOX 37428, RALEIGH, NC, 27627, US

(21) Appl. No.: 11/178,579

(22) Filed: Jul. 11, 2005

(30) Foreign Application Priority Data
Aug. 4, 2004 (KR) 10-2004-0061268

(51) Int. Cl. H01L 21/425; C23C 14/00

(52) U.S. Cl. 438/514; 427/523

(57) ABSTRACT

An ion source for ionizing a source gas includes an arc chamber housing defining an arc chamber to receive the source gas. The arc chamber has a first region and a second region. An electron emitting device is disposed in the arc chamber adjacent the first region and is adapted to emit electrons into the first and the second regions to ionize the source gas. An electron returning device is disposed in the arc chamber adjacent the second region and is adapted to return at least some of the electrons emitted from the electron emitting device into the second region. A gas supply system is adapted to direct the source gas into the first region and into the second region. According to some embodiments, the gas supply system is adapted to provide a greater mass flow rate of the source gas into the first and second regions than is provided into other regions of the arc chamber.

### CROSS-REFERENCE TO RELATED APPLICATION

This application claims the benefit of priority under 35 USC § 119 to Korean Patent Application No. 2004-61268, filed Aug. 4, 2004, the disclosure of which is incorporated herein by reference in its entirety.

### FIELD OF THE INVENTION

The present invention relates to ion sources and ion implanters having ion sources and, more particularly, to ion sources for generating ions for doping a semiconductor substrate in a semiconductor manufacturing process, and ion implanters including such ion sources.

### BACKGROUND OF THE INVENTION

Generally, a semiconductor device is manufactured through fabrication processes for forming a circuit on a semiconductor substrate such as a silicon wafer, an electrical die sorting (EDS) process for inspecting electrical characteristics of the circuit formed on the substrate, and a packaging process for sealing the semiconductor device using epoxy resin.

The fabrication processes are usually divided into a deposition process for forming a layer on the substrate, a chemical mechanical polishing (CMP) process for planarizing the layer, a photolithography process for forming a photoresist pattern on the layer, an etching process for forming an electrical pattern from the layer using the photoresist pattern, an ion implantation process for implanting ions into a predetermined region of the substrate, a cleaning process for removing particles from the substrate, and an inspection process for inspecting electrical failures of the pattern.

The ion implantation process is performed to obtain a doped region on a semiconductor substrate by implanting ions into a predetermined portion of the substrate. This ion implantation process is executed using an ion implanter that includes an ion source. Known ion sources for generating ions are disclosed in U.S. Pat. No. 5,262,652 to Bright et al., U.S. Pat. No. 6,184,532 to Abbott et al., U.S. Pat. No. 6,022,258 to Dudniknov et al., and U.S. Patent Application Publication No. 2002/0185607 to Reyes, for example.

The known ion source has an arc chamber in which ions are generated and a filament for thermally emitting electrons into the arc chamber. A filament current is applied to the filament so as to thermally emit the electrons, and an arc voltage biased relative to the filament current is applied at the arc chamber. Thus, the filament serves as a cathode whereas the arc chamber functions as an anode.

The filament is electrically insulated from the arc chamber by interposing an insulation member between the filament and the arc chamber. The electrons are thermally emitted from the heated filament by applying the filament current to the filament. The emitted electrons collide with a source gas provided in the arc chamber, thereby generating ions in the arc chamber.

FIG. 1 is a horizontal cross-sectional view illustrating a prior art ion source 30. FIG. 2 is a vertical cross-sectional view illustrating the ion source 30 of FIG. 1.

Referring to FIGS. 1 and 2, the prior art ion source 30 includes an arc chamber housing 32, a filament 34 and a reflector 36. The arc chamber housing 32 defines an arc chamber 33.

The filament 34 is disposed in the arc chamber 33. The filament 34 is adjacent to a first sidewall 32a of the arc chamber housing 32. A first insulation member 38 is interposed between the filament 34 and the first sidewall 32a so that the filament 34 is electrically insulated from the arc chamber housing 32.

The reflector 36 is disposed in the arc chamber 33. The reflector 36 is adjacent to a second sidewall 32b of the arc chamber housing 32. The second sidewall 32b is opposed to the first sidewall 32a. A second insulation member 40 is disposed between the reflector 36 and the second sidewall 32b such that the reflector 36 is also electrically insulated from the arc chamber housing 32.

The filament 34 is electrically connected to a filament power source (not shown). The filament 34 emits electrons into the arc chamber 33. Since a negative voltage is applied to the reflector 36, the reflector 36 repulses the electrons moving toward the second sidewall 32b back to an interior region of the arc chamber 33. Thus, the source gas ionization efficiency may be improved. A positive voltage is applied to the sidewalls of the arc chamber housing 32 so that ions generated by the collision between the electrons and molecules of the source gas are returned or repelled back into the arc chamber 33.

A gas supply line 42 extends through a central portion of a third sidewall 32c of the arc chamber housing 32. The third sidewall 32c is perpendicular to the first sidewall 32a and the second sidewall 32b. An ion extraction line 44 extends through a fourth sidewall 32d of the arc chamber housing 32. The fourth sidewall 32d is opposed to the third sidewall 32c. The gas supply line 42 is connected to a gas feeding line 46 to provide the source gas in the arc chamber 33.

### SUMMARY OF THE INVENTION

According to embodiments of the present invention, an ion source for ionizing a source gas includes an arc chamber housing defining an arc chamber to receive the source gas. The arc chamber has a first region and a second region. An electron emitting device is disposed in the arc chamber adjacent the first region and is adapted to emit electrons into the first and the second regions to ionize the source gas. An electron returning device is disposed in the arc chamber adjacent the second region and is adapted to return at least some of the electrons emitted from the electron emitting device into the second region. A gas supply system is adapted to direct the source gas into the first region and into the second region. According to some embodiments, the gas supply system is adapted to provide a greater mass flow rate of the source gas into the first and second regions than is provided into other regions of the arc chamber.

According to embodiments of the present invention, an ion implanter for implanting a material into a substrate includes an ion source, an end station, and a transferring unit. The ion source is adapted to ionize a source gas containing the material to be implanted into the substrate. The end station unit is adapted to handle the substrate to implant ions provided from the ion source. The transferring unit connects the ion source to the end station unit to transfer the ions from the ion source to the end station unit. The ion source includes an arc chamber housing defining an arc chamber to receive the source gas. The arc chamber has a first region and a second region. An electron emitting device is disposed in the arc chamber adjacent the first region and is adapted to emit electrons into the first and second regions to ionize the source gas. An electron returning device is disposed in the arc chamber adjacent the second region and is adapted to return at least some of the electrons emitted from the electron emitting device into the second region. A gas supply system is adapted to direct the source gas into the first region and into the second region. According to some embodiments, the gas supply system is adapted to provide a greater mass flow rate of the source gas into the first and second regions than is provided into other regions of the arc chamber.

According to further embodiments of the present invention, a method for ionizing a source gas includes: directing the source gas into a first region of an arc chamber and into a second region of the arc chamber; emitting electrons from an electron emitting device into the first and the second regions to ionize the source gas, wherein the electron emitting device is disposed in the arc chamber adjacent the first region; and returning at least some of the electrons emitted from the electron emitting device into the second region using an electron returning device, wherein the electron returning device is disposed in the arc chamber adjacent the second region. According to some embodiments, the step of directing the source gas into the first region and into the second region includes providing a greater mass flow rate of the source gas into the first and second regions than is provided into a third region of the arc chamber located between the electron emitting device and the electron returning device and between the first and second regions.

Further features, advantages and details of the present invention will be appreciated by those of ordinary skill in the art from a reading of the figures and the detailed description of the preferred embodiments that follow, such description being merely illustrative of the present invention.

### BRIEF DESCRIPTION OF THE DRAWINGS

The above and other features and advantages of the present invention will become readily apparent by reference to the following detailed description when considered in conjunction with the accompanying drawings wherein:

FIG. 1 is a horizontal cross-sectional view illustrating a prior art ion source;

FIG. 2 is a vertical cross-sectional view illustrating the prior art ion source of FIG. 1;

FIG. 3 is a horizontal cross-sectional view illustrating an ion source according to embodiments of the present invention;

FIG. 4 is a vertical cross-sectional view illustrating the ion source of FIG. 3;

FIG. 5 is a circuit diagram illustrating a filament power source and an arc power source in accordance with embodiments of the present invention;

FIG. 6 is a cross-sectional view illustrating the ion source of FIGS. 3 and 4 including an alternative electron emitting device and an alternative electron returning device in accordance with embodiments of the present invention;

FIG. 7 is a cross-sectional view illustrating a gas supply system in accordance with further embodiments of the present invention;

FIG. 8 is a cross-sectional view illustrating a gas supply system in accordance with further embodiments of the present invention;

FIG. 9 is an enlarged, fragmentary, cross-sectional view illustrating a gas injector in accordance with further embodiments of the present invention;

FIG. 10 is a schematic cross-sectional view illustrating an ion implanter in accordance with embodiments of the present invention including the ion source of FIG. 3;

FIG. 11 is an enlarged cross-sectional view illustrating an end station unit of the ion implanter of FIG. 10; and

FIG. 12 is a graph illustrating ion currents of ion beams generated from ion sources according to a Comparative Example and Examples in accordance with embodiments of the present invention.

### DETAILED DESCRIPTION OF EMBODIMENTS OF THE INVENTION

The present invention now will be described more fully hereinafter with reference to the accompanying drawings, in which illustrative embodiments of the invention are shown. In the drawings, the relative sizes of regions or features may be exaggerated for clarity. This invention may, however, be embodied in many different forms and should not be construed as limited to the embodiments set forth herein; rather, these embodiments are provided so that this disclosure will be thorough and complete, and will fully convey the scope of the invention to those skilled in the art.

It will be understood that when an element or layer is referred to as being “on”, “connected to”, “coupled to” or “combined with” another element or layer, it can be directly on, connected or coupled to the other element or layer or intervening elements or layers may be present. In contrast, when an element is referred to as being “directly on,” “directly connected to”, “directly coupled to” or “directly combined with” another element or layer, there are no intervening elements or layers present. Like reference numerals refer to like elements throughout. As used herein, the term “and/or” includes any and all combinations of one or more of the associated listed items. It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the face through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

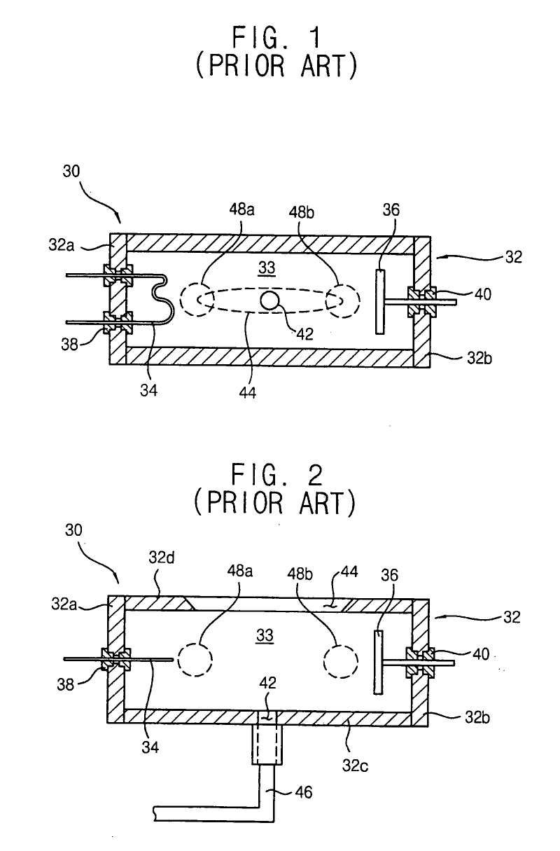

As appreciated by the present inventors, in the prior art ion sources such as the ion source 30 (FIGS. 1 and 2), the source gas is more actively ionized in a first inner region 48a and a second inner region 48b of the arc chamber 33 than elsewhere in the arc chamber 33. The first inner region 48a and the second inner region 48b are adjacent to the filament 34 and the reflector 36, respectively. Because the electrons emitted from the filament 34 have maximum kinetic energy at the first and second inner regions 48a and 48b, the source gas also has its maximum levels of ionization in the first and second inner regions 48a and 48b. Because the gas supply line 42 is disposed between the first inner region 48a and the second inner region 48b, however, the source gas may not be provided directly to the first and the second inner regions 48a and 48b. Thus, the overall ionization efficiency of the source gas in the arc chamber 33 may be reduced. As a result, the throughput of an ion implanting process may be reduced and non-ionized source gas may contaminate the ion implanter.

In accordance with embodiments of the present invention, an ion source and/or an ion implanter incorporating the same are provided which may overcome the shortcomings of prior art ion sources and ion implanters and provide improved efficiency in the ionization of a source gas. In accordance with embodiments of the present invention, an ion source is constructed and employed such that a source gas is directed into a first region of an arc chamber adjacent an electron emitting device and also into a second region of the arc chamber adjacent an electron returning device.

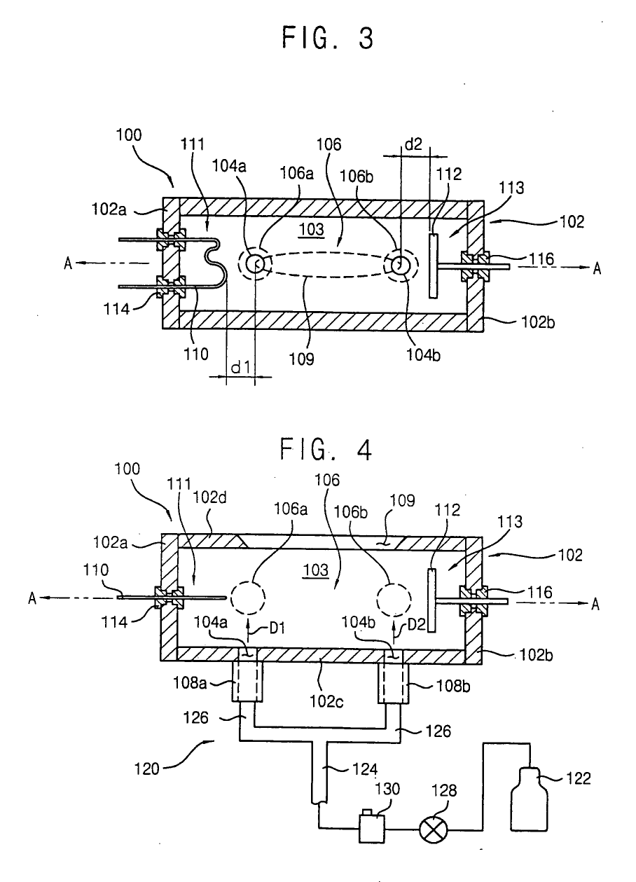

FIG. 3 is a horizontal cross-sectional view illustrating an ion source 100 according to embodiments of the present invention. FIG. 4 is a vertical cross-sectional view illustrating the ion source 100. The ion source 100 may be used to perform an ion implantation process on a semiconductor substrate such as a silicon wafer to form contact regions such as source/drain regions.

The ion source 100 includes an arc chamber housing 102, an electron emitting device 111 and an electron returning device 113. The arc chamber housing 102 defines an arc chamber 103 therein. The electron emitting device 111 cooperates with the electron returning device 113. The electron emitting device 111 includes a filament 110. The electron returning device 113 includes a reflector 112.

The arc chamber 103 provides a space or volume wherein a source gas is ionized. More particularly, the source gas is ionized in a region 106 extending from the filament 110 to the reflector 112 to form a plasma therein. The source gas includes ion precursors. The filament 110 emits electrons into the space of the arc chamber 103 so as to ionize the source gas. The reflector 112 returns or repulses the electrons emitted from the filament 110 toward the region 106 of the arc chamber 103.

The filament 110 and the reflector 112 are spaced apart from one another along a longitudinal axis A-A. The region 106 is interposed between the filament 110 and the reflector 112 along the axis A-A. The reflector 112 faces the filament 110. The filament 110, the reflector 112 and the portion of the region 106 are generally aligned along the axis A-A.

The arc chamber housing 102 includes a first sidewall 102a, a second sidewall 102b, a third sidewall 102c and a fourth sidewall 102d. The first sidewall 102a and the second sidewall 102b are substantially opposed to each other. The third sidewall 102c and the fourth sidewall 102d are substantially opposed to each other. The first sidewall 102a is substantially parallel to the second sidewall 102b. The third sidewall 102c is substantially in parallel with the fourth sidewall 102d. In addition, the third and the fourth sidewalls 102c and 102d are substantially perpendicular to the first and the second sidewalls 102a and 102b. Thus, the arc chamber 103 is defined by the first, second, third and fourth sidewalls 102a, 102b, 102c and 102d.

The filament 110 is disposed in the arc chamber 103. The filament 110 may be located adjacent to the first sidewall 102a. Portions of the filament 110 extend outside of the arc chamber 103 through the first sidewall 102a.

The reflector 112 is also disposed in the arc chamber 103. The reflector 112 is located adjacent to the second sidewall 102b. A portion of the reflector 112 extends outside of the arc chamber 103 through the second sidewall 102b. The reflector 112 opposes and faces the filament 110.

The filament 110 is electrically insulated from the first sidewall 102a by one or more first insulation members 114 positioned on and/or through the first sidewall 102a. The first insulation members 114 are interposed between the filament 110 and the first sidewall 102a. The first insulation members 114 enclose the respective extending portions of the filament 110.

The reflector 112 is electrically insulated from the second sidewall 102b by a second insulation member 116 that partially encloses the extending portion of the reflector 112. The second insulation member 116 is disposed on and/or through the second sidewall 102b and is interposed between the extending portion and the sidewall 102b.

According to alternative embodiments (not shown), the filament 110 and the reflector 112 may be separated from the first and the second sidewalls 102a and 102b, respectively, by predetermined distances. In this case, the filament 110 and the reflector 112 may be electrically insulated from the first and the second sidewalls 102a and 102b without employing the first and the second insulation members 114 and 116.

According to further embodiments (not shown), the first sidewall 102a may include first holes having diameters substantially larger than those of the extending portions of the filament 110. The extending portions of the filament 110 pass through the first holes with predetermined surrounding gaps so that the filament 110 is electrically insulated from the first sidewall 102a. Additionally, the second sidewall 102b may have a second hole having a diameter substantially larger than that of the extending portion of the reflector 112. The extending portion of the reflector 112 passes through the second hole with a predetermined surrounding gap so that the reflector 112 is electrically insulated from the second sidewall 102b.

A first gas supply inlet 104a and a second gas supply inlet 104b extend through the third sidewall 102c. The inlets 104a and 104b are contiguous with and fluidly communicate with the arc chamber 103. The source gas is provided into the arc chamber 103 through the first and the second gas supply inlets 104a and 104b during the ionization process.

The first gas supply inlet 104a directs the source gas into a first inner region or volume 106a of the arc chamber 103 located above the first gas supply inlet 104a. The first inner region 106a is located adjacent to the filament 110. The second gas supply inlet 104b directs the source gas into a second inner region or volume 106b of the arc chamber 103 located above the second gas supply inlet 104b. The region 106b is disposed adjacent to the reflector 112. In particular, the region 106a is located more closely adjacent the filament 110 than is the region 106b, and the region 106b is located more closely adjacent the reflector 112 than is the region 106a. Also, in accordance with some embodiments and as shown, the region 106a is located more closely adjacent to the filament 110 than to the reflector 112, and the region 106b is located more closely adjacent to the reflector 112 than to the filament 110.

According to some embodiments, and as illustrated, the gas supply inlets 104a, 104b are each adapted to inject the source gas directly into the arc chamber 103 such that the source gas flows directly and unimpeded (i.e., by structural elements of the arc chamber housing 102 or the like) to the respective intended regions 106a, 106b. That is, the first gas flow from the inlet 104a follows a first substantially direct flow line or path from entry into the arc chamber 103 to the region 106a. Likewise, the second gas flow from the inlet 104b follows a second substantially direct flow line or path from entry into the arc chamber 103 to the region 106b.

In accordance with some embodiments of the present invention, the source gas is introduced through the inlets 104a, 104b such that the source gas is directed into the regions 106a, 106b such that the initial, pre-ionized source gas is provided into or through the regions 106a, 106b at a greater mass flow rate than into or through other regions in the arc chamber 103 where less active ionization occurs (i.e., those regions not between and adjacent each of the electron emitting device and the electron returning device). As a result, the respective mass flow rates of source gas into or through the various regions of the arc chamber 103 (including the regions 104a, 104b) are more proportional to the densities of ionizing (i.e., energized) electrons in those regions of the arc chamber. More efficient ionization of the ionizable material of the source gas is provided.

The ion source 100 is configured such that the first gas supply inlet 104a preferentially directs a first flow of the source gas into the region 106a, and the second gas supply inlet 104b preferentially directs a second flow of the source gas into the region 106b. That is, substantially more of the first and second source gas flows are directed by the inlets 104a, 104b into the respective regions 106a, 106b than into the region of the arc chamber 103 between the regions 106a, 106b along the axis A-A or elsewhere in the arc chamber 103. Additionally, substantially more of the first flow of the source gas may be introduced from the inlet 104a into the region 106a than into the region 106b, and substantially more of the second flow of the source gas is introduced from the inlet 104b into the region 106b than into the region 106a.

According to some embodiments and as shown, the inlets 104a, 104b are spaced apart along the axis A-A such that the inlet 104a is nearer the filament 110 and the region 106a than the inlet 104b, and the inlet 104b is nearer the reflector 112 and the region 106b than the inlet 104a. According to some embodiments, the inlets 104a and 104b direct their source gas flows into the chamber 103 in directions D₁ and D₂, respectively, that are transverse to the axis A-A. According to some embodiments and as illustrated, the directions D₁ and D₂ are substantially perpendicular to the axis A-A. The flow paths of the first and second gas flows from the inlets 104a and 104b extend in the directions D₁ and D₂, which intersect the respective regions 106a and 106b.

The first gas supply inlet 104a is spaced apart from the filament 110 along the longitudinal axis A-A a first distance d1 (measured from the center of the inlet 104A). The second gas supply inlet 104b is separated from the reflector 112 along the longitudinal axis A-A by a second distance d2 (measured from the center of the inlet 104b). According to some embodiments, the first distance d1 is in the range of from about 5 to 15 mm and the second distance d2 is in the range of from about 5 to 15 mm. According to some embodiments, the diameter of the first gas supply inlet 104a is substantially the same as the diameter of the second gas supply inlet 104b. According to some embodiments, the diameter of each inlet 104a, 104b is in the range of from about 3 to 5 mm.

A first fitting or connecting member 108a and a second fitting or connecting member 108b are disposed on the third sidewall 102c. A gas supply system 120 is connected to the arc chamber 103 through the first and the second connecting members 108a and 108b. The first and the second gas supply inlets 104a and 104b extend to the outside of the arc chamber 103 through the third sidewall 102c, and then are connected to the first and the second connecting members 108a and 108b, respectively.

The gas supply system 120 includes a gas source 122, a first line 124 and two second lines 126. The source gas is provided from the gas source 122 into the arc chamber 103 through the first line 124 and the second lines 126. The first line 124 is divided into the second lines 126 near the first and the second connecting members 108a and 108b. The second lines 126 are connected to the first and second gas supply inlets 104a and 104b through the first and the second connecting members 108a and 108b, respectively.

The gas supply system 120 further includes a mass flow controller (MFC) 130 and a gate valve 128 installed in the first line 124 so as to control a flow rate of the source gas introduced into the arc chamber 103.

According to some embodiments, the source gas includes an element such as boron (B), phosphorus (P), arsenic (As), antimony (Sb), etc. These elements may change the electrical characteristics of a layer formed on a substrate and/or the substrate. According to some embodiments, the source gas includes BF₃. When the source gas including BF₃ is provided into the arc chamber 102, ions including ₁₀B⁺, ₁₀BF⁺, ₁₀BF⁺, ₁₁B⁺ and/or ₁₁BF²⁺ may be generated in the arc chamber 103 as a result of collisions between the source gas and electrons emitted from the filament 110. According to some embodiments of the present invention, the source gas also includes an inactive gas such as an argon (Ar) gas or a nitrogen (N₂) gas.

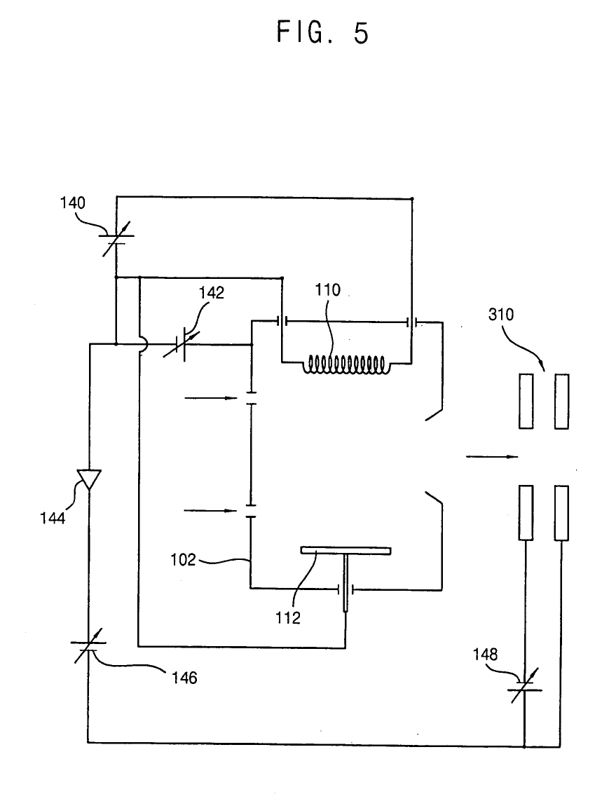

FIG. 5 is a circuit diagram illustrating a filament power source 140 and an arc power source 142 in accordance with embodiments of the present invention. The filament power source 140 is electrically connected to the filament 110 (FIG. 3), and the arc power source 142 is electrically connected to the arc chamber housing 102 (FIG. 3).

Referring to FIGS. 3 to 5, a filament current flows from the filament power source 140 to the filament 110 to thereby thermally emit electrons from the filament 110 into the arc chamber 103. An arc voltage biased relative to the filament current is applied from the arc power source 142 to the arc chamber housing 102.

The extending portions of the filament 110 are electrically connected a cathode terminal and an anode terminal of the filament power source 140. An anode terminal of the arc power source 142 is electrically connected to the arc chamber 102, whereas a cathode terminal of the arc power source 142 is electrically connected to the cathode terminal of the filament power source 140. The cathode terminals of the filament power source 140 and the arc power source 142 are also electrically connected to a source ground 144.

An ion extractor 310 is connected to the arc chamber 103 through an ion extraction outlet or line 109 extending through the fourth sidewall 102d of the arc chamber housing 102. The ion extractor 310 extracts the ions from the arc chamber 103 through the ion extraction line 109. The ion extractor 310 is electrically connected to a cathode terminal of an extraction power source 146. A suppression power source 148 is electrically connected to the ion extractor 310 and the extraction power source 146 so as to prevent the generation of radiation from the ion extractor 310.

According to some embodiments of the present invention, the reflector 112 of the electron returning device 113 has a negative potential to repulse the electrons emitted from the filament 110 toward the first and the second regions 106a and 106b of the arc chamber 103. As shown in FIG. 5, the reflector 112 is electrically connected to the cathode terminal of the filament power source 140.

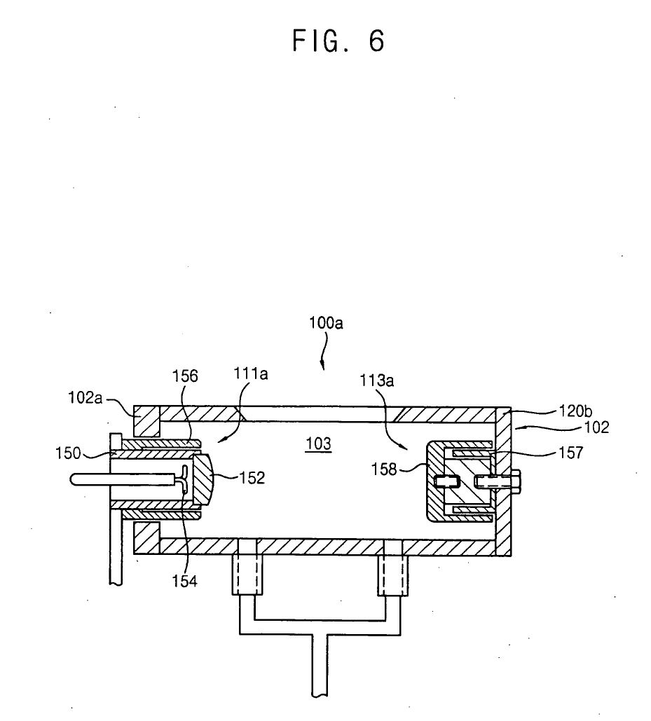

According to some embodiments of the present invention, the ion source 100 includes an electron emitting device including a cathode cap 152 for emitting electrons into the arc chamber 103. FIG. 6 is a cross-sectional view illustrating an alternative ion source 100a including an alternative electron emitting device 11a and an alternative electron returning device 113a in accordance with embodiments of the present invention.

Referring to FIGS. 3, 5 and 6, the electron emitting device 11a includes a tube 150, the cathode cap 152, and a filament 154. The tube 150 extends into the arc chamber 103 through a first sidewall 102a of the arc chamber housing 102. The cathode cap 152 is disposed at an end portion of the tube 150. The filament 154 is installed in the tube 150. The filament 154 is electrically connected to the filament power source 140. The tube 150 is electrically insulated from the arc chamber housing 102 by a first insulation member 156 that encloses the tube 150.

Electrons emitted from the filament 154 collide with the cathode cap 152 so that the cathode cap 152 is heated by the electrons. When the cathode cap 152 is sufficiently heated, the heated cathode cap 152 thermally emits electrons into the arc chamber 103.

As shown in FIG. 6, the electron returning device 113a employs a repeller 158 in place of the reflector 112. The repeller 158 faces and cooperates with the electron emitting device 111a. The repeller 158 is disposed on the second sidewall 102b of the arc chamber housing 102. The repeller 158 may be substantially opposed to the cathode cap 152. The repeller 158 is also electrically insulated from the arc chamber housing 102 by a second insulation member 157 interposed between the repeller 158 and the second sidewall 102b. The electrically floated repeller 158 serves to return or repulse the electrons emitted from the filament 110 toward the first and the second regions 106a and 106b of the arc chamber 103. When the repeller 158 is used as the electron returning device, the electrons emitted into the arc chamber 103 are collected by the electrically floated repeller 158. Once the repeller 158 has a negative potential due to the collected electrons, the repeller 158 repulses the electrons emitted from the filament 110 toward the first and the second regions 106a and 106b of the arc chamber 103, thereby improving the efficiency of the ionization of the source gas.

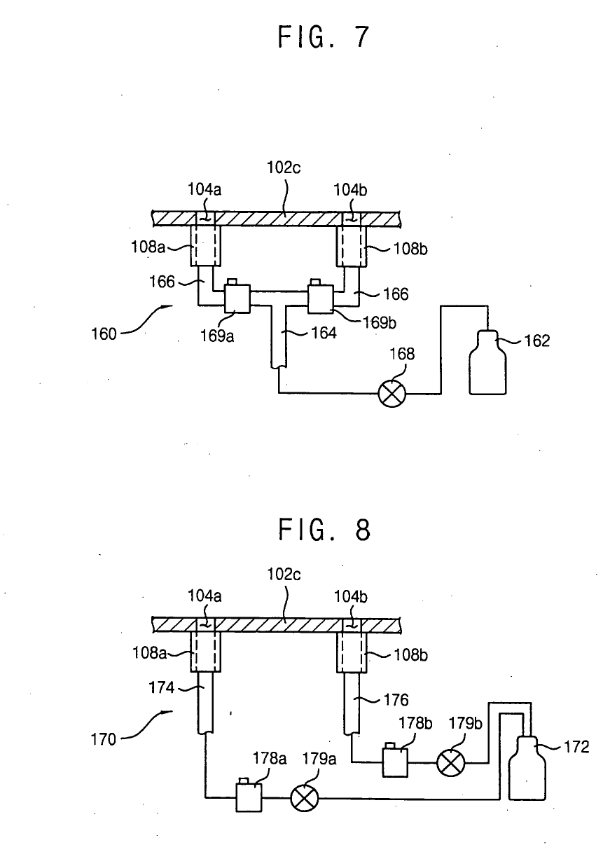

FIG. 7 is a cross-sectional view illustrating a gas supply system 160 in accordance with further embodiments of the present invention. Referring to FIGS. 4 and 7, the gas supply unit 160 includes a gas source 162, a first line 164, a pair of second lines 166, a gate valve 168, a first MFC 169a and a second MFC 169b.

The gate valve 168 is installed in the first line 164 connected to the gas source 162. The second lines 166 diverge from the first line 164. The second lines 166 are respectively connected to the first connecting member 108a and the second connecting member 108b disposed on the third sidewall 102c of the arc chamber housing 102. The first and the second MFCs 169a and 169b are installed in the second lines 108a and 108b, respectively. Each of the first and the second MFCs 169a and 169b is operable to selectively adjust a flow rate of the source gas flowing through a respective one of the inlets 104a and 104b and into the arc chamber 103. As described above, the source gas is introduced into the first region 106a and the second region 106b of the arc chamber 103. Here, a first flow rate of the source gas provided into the first region 106a may be substantially identical to a second flow rate of the source gas introduced into the second region 106b. Alternatively, the MFCs 169a, 169b can be selectively adjusted to provide different flow rates through the inlets 104a and 104b. In accordance with some embodiments, the first flow rate through the inlet 104a is substantially larger than the second flow rate through the inlet 104b. This may be advantageous because a first density of electrons near the filament 110 is relatively larger than a second density of the electrons adjacent to the reflector 112. According to some embodiments, the ratio between the first flow rate and the second flow rate is in the range of from about 1.0:1.0 to about 2.0:1.0.

FIG. 8 is a cross-sectional view illustrating a gas supply system 170 in accordance with further embodiments of the present invention. Referring to FIGS. 4 and 8, the gas supply system 170 includes a gas source 172, a first line 174, and a second line 176 separated from the first line 174.

The first line 174 and the second line 176 are respectively connected to the first gas supply inlet 104a and the second gas supply inlet 104b through the first connecting member 108a and the second connecting member 108b. The source gas is introduced from the gas source 172 into the arc chamber 103 through the first and the second lines 174 and 176 and the first and the second gas supply inlets 104a and 104b. To control the flow rates of the source gas, a first gate valve 179a and a first MFC 178a are installed in the first line 174, and a second gate valve 179b and a second MFC are installed in the second line 176.

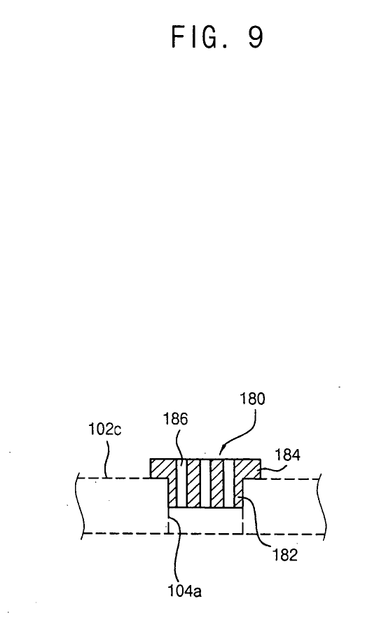

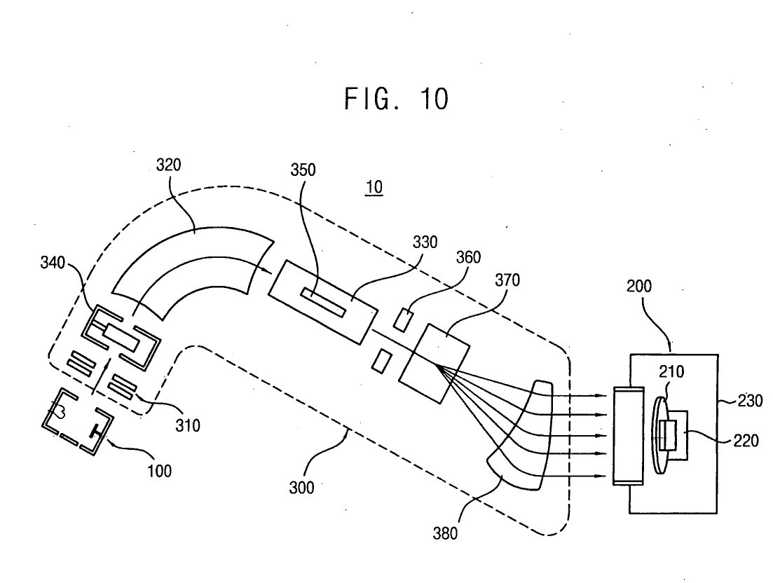

FIG. 9 is a sectional view illustrating a gas injector 180 in accordance with embodiments of the present invention. Referring to FIGS. 3 and 9, the ion source 100 further includes first and second gas nozzles or injectors 180 positioned in each of the first and the second gas supply inlets 104a and 104b, respectively (only one of the gas injectors 180 is shown in FIG. 9). Each gas injector 180 includes a body portion 182 inserted into the respective gas supply inlet 104a and 104b and a flange or head portion 184 mounted on the inside of the third sidewall 102c. The head portion 184 may be integrally formed with the body portion 182. The head portion 184 may have a size substantially larger than that of the body portion 182. A plurality of gas injection holes 186 are formed through the head portion 184 and the body portion 182. The gas injectors 180 may serve to increase the efficiency of the source gas ionization by increasing the velocity of the source gas flowed from the inlets 104a, 104b and thereby more directly introducing the source gas into the first and the second regions 106a and 106b adjacent to the filament 110 and the reflector 112, respectively.

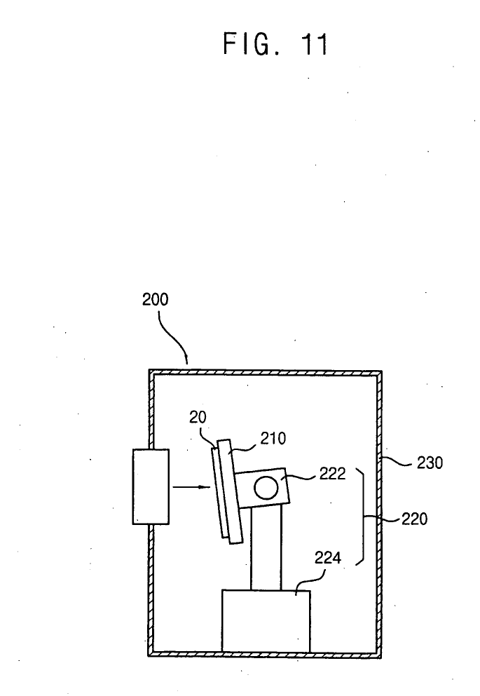

Referring to FIGS. 10 and 11, an ion implanter 10 includes the ion source 100, an end station unit 200 and a transferring unit 300. FIG. 10 is a schematic cross-sectional view illustrating the ion implanter 10. FIG. 11 is an enlarged cross-sectional view illustrating the end station unit 200.

The ion implanter 10 directs ions from the ion source 100 into a predetermined portion of a semiconductor substrate 20 as described above. The end station unit 200 handles the semiconductor substrate 20 to implant the ions into the desired portion of the semiconductor substrate 20. The transferring unit 300 connects the ion source 100 to the end station unit 200. The transferring unit 300 transmits the ions from the ion source 100 to the end station unit 200.

As described above, the ion source 100 includes the arc chamber housing 102 for providing the space wherein the ions are generated, the electron emitting device for providing the electrons into the arc chamber 103, the electron returning device for repulsing the electrons within the arc chamber 103, and a gas supply system for providing the source gas into the arc chamber 103. The ions generated from the ion source 100 are implanted into the desired portion of the semiconductor substrate 20 loaded in the end station unit 200.

The end station unit 200 includes an ion injection chamber 230, a chuck 210 for holding the semiconductor substrate, and a driving unit 220 connected to the chuck 210. The chuck 210 and the driving unit 220 are disposed in the ion injection chamber 230. The driving unit 220 tilts the semiconductor substrate 20 loaded on the chuck 210 so as to control an incidence angle of an ion beam. The driving unit 220 also moves the chuck 210 vertically to scan the ion beam along the semiconductor substrate 20 positioned on the chuck 210.

The chuck 210 may hold the semiconductor substrate 20 using electrostatic force. The driving unit 220 includes a first moving member 222 for tilting the chuck 210 and a second moving member 224 for moving the chuck 210 along a vertical direction. The first moving member 222 adjusts a tilt angle of the semiconductor substrate 20 positioned on the chuck 210 so as to avoid a channeling effect caused by a crystalline structure of the semiconductor substrate 20 during the implantation process. For example, the first moving member 222 tilts the semiconductor substrate 20 by an angle of about ±7° along a vertical line relative to the semiconductor substrate 20 when the ion beam is horizontally irradiated onto the semiconductor substrate 20. That is, the incidence angle of the ion beam is about 83° when the first moving member 222 tilts the semiconductor substrate 20 at an angle of about ±7°.

According to some embodiments, the end station unit 200 includes a batch-type chuck for simultaneously holding a plurality of substrates instead of the single-type chuck 210 as shown in FIG. 11.

The transferring unit 300 includes an ion extractor 310, an analyzer magnet 320 and an accelerator 330. The ion extractor 310 extracts the ions from the ion source 100. The analyzer magnet 320 selects the ions to be implanted into the portion of the semiconductor substrate 20 from among the ions extracted by the ion extractor 310. The accelerator 330 accelerates the selected ions from the analyzer magnet 320.

An extraction voltage is applied to the ion extractor 310 to extract the ions from the arc chamber 103. A first polarity converter 340 is disposed between the ion extractor 310 and the analyzer magnet 320. The first polarity converter 340 converts the polarity of the ion beam including the ions extracted by the ion extractor 310. The first polarity converter 340 may include an electron donating substance such as solid magnesium and a heater. When the heater heats the solid magnesium up to a suitable temperature (e.g., about 450° C.), vaporized magnesium molecules emitted from the solid magnesium may collide with the ions extracted by the ion extractor 310. The polarity of the ion beam is converted from positive to negative in accordance with the collisions between the vaporized magnesium molecules and the extracted ions. The analyzer magnet 320 selects desired ions from among the ions included in the ion beam having the negative polarity.

The ion beam including the ions selected by the analyzer magnet 320 is induced to the accelerator 330. The selected ions are then accelerated in the accelerator 330 to have various energy levels. In addition, a second polarity converter 350 is disposed in the accelerator 330 to convert the polarity of the ion beam including the ions passing through the accelerator 330. The second polarity converter 350 converts the polarity of the ion beam using a stripping gas. Thus, the second polarity converter 350 may include a stripper.

The accelerator 330 may include a first accelerating member for accelerating the ion beam having the negative polarity, and a second accelerating member for accelerating the ion beam having the positive polarity. To change the polarity of the ion beam from the negative polarity to the positive polarity, the second polarity converter 350 is disposed between the first accelerating member and the second accelerating member. The negative polarity ion beam accelerated by the first accelerating member is converted to the positive polarity ion beam by the stripping gas provided from the second polarity converter 350. The converted positive polarity ion beam is accelerated using the second accelerating member. The stripping gas may include a nitrogen gas or an argon gas. The negative ions included in the negative polarity ion beam are converted to positive ions by the collisions between the negative ions and molecules of the stripping gas.

The transferring unit 300 includes an ion filter 360, a scanner magnet 370 and a collimator magnet 380. The ion filter 360 selects ions having a desired energy level or levels. The scanner magnet 370 scans a horizontally extending ion beam including the ions having the desired energy level(s). The collimator magnet 380 provides the ion beam in parallel relative to an entire scanned region of the substrate 20.

According to embodiments of the present invention, the ion implanter 10 includes a movable Faraday cup system and a dose Faraday cup system in order to measure a dose amount of the ions and a uniformity of an ion current of the ion beam having a ribbon shape formed by the scanner magnet 370 and the collimator magnet 380. The movable Faraday cup system may move along an extension direction of the ion beam, and the dose Faraday cup system may be positioned behind the chuck 210.

### EXAMPLES

### Estimation of Ionization Efficiencies of Ion Sources

Ion sources having the above-described structure were constructed as Examples 1 to 6, and an ion source of the prior art design was used as a Comparative Example. Ion currents of ion beams relative to various applied acceleration energies were measured to estimate ionization efficiencies of the ion sources according to the Comparative Example and the Examples 1 to 6.

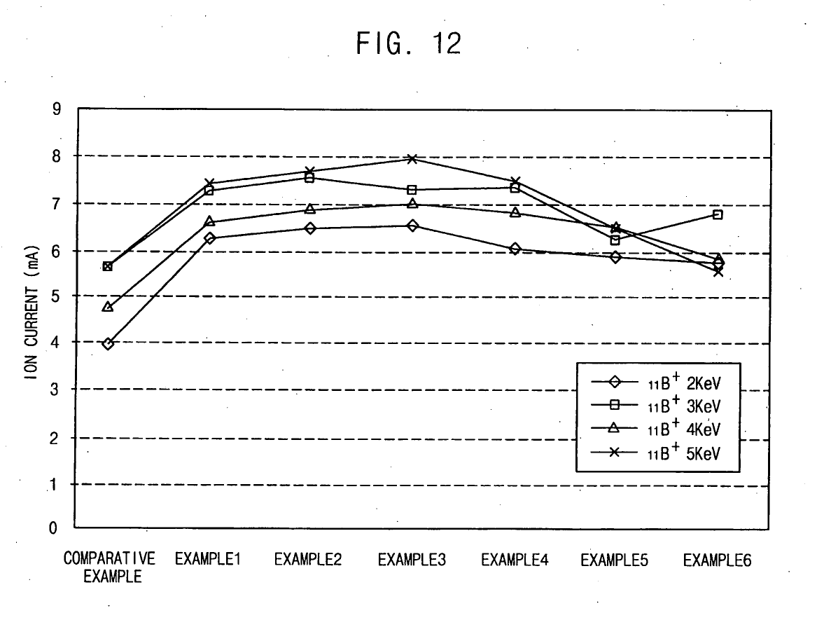

The following Table shows the measured ion currents of ion beams generated from the ion sources according to the Comparative Example and the Examples 1 to 6 for each of eight applied acceleration energies. FIG. 12 is a graph illustrating the ion currents of the ion beams generated from the ion sources according to the Comparative Example and the Examples 1 to 6.

| | TABLE | | | | | | | |
|---|---|---|---|---|---|---|---|---|
| | Acceleration energy [Kev] | | | | | | | |
| | 0.5 | 0.6 | 0.7 | 1.0 | 2.0 | 3.0 | 4.0 | 5.0 |
| Comparative | 1.65 | 1.88 | 1.80 | 2.64 | 3.96 | 5.62 | 4.78 | 5.62 |
| Example | | | | | | | | |
| [mA] | | | | | | | | |
| Example 1 | 2.16 | 2.12 | 2.96 | 2.65 | 6.26 | 7.26 | 6.63 | 7.44 |
| [mA] | | | | | | | | |
| Example 2 | 1.84 | 2.33 | 2.89 | 2.69 | 6.48 | 7.56 | 6.89 | 7.68 |
| [mA] | | | | | | | | |
| Example 3 | 1.77 | 2.34 | 2.84 | 2.75 | 6.52 | 7.31 | 7.02 | 7.95 |
| [mA] | | | | | | | | |
| Example 4 | 1.81 | 2.27 | 2.88 | 2.92 | 6.06 | 7.35 | 6.84 | 7.49 |
| [mA] | | | | | | | | |
| Example 5 | 1.88 | 2.17 | 2.71 | 2.60 | 5.89 | 6.23 | 6.51 | 6.46 |
| [mA] | | | | | | | | |
| Example 6 | 1.90 | 2.07 | 2.24 | 2.68 | 5.77 | 6.78 | 5.82 | 5.57 |
| [mA] | | | | | | | | |
| Estimation | +14% | +19% | +52% | same | +55% | +26% | +38% | +26% |

In the above Table and FIG. 12, a BF₃ gas was used as a source gas and the ion beams including ₁₁B⁺ ions generated from the ion sources were formed using the analyzer magnet. The ion currents of the ion beams were measured using the movable Faraday cup system and the dose Faraday cup system.

As shown in the above Table and FIG. 12, although the ion currents of the ion beams varied according to the applied acceleration energies, the ion currents of the ion beams generated from the ion sources of the Examples 1 to 6 were substantially larger than the ion current of the ion beam generated from the ion source of the Comparative Example. Therefore, the ion sources constructed in accordance with embodiments of the present invention had ionization efficiency of a source gas substantially greater than that of the prior art ion source.

According to embodiments of the present invention, an ion source may have an improved source gas ionization efficiency because the source gas is provided directly into a first region adjacent to an electron emitting device through a first gas supply inlet and is directly provided into a second region adjacent to an electron returning device through a second gas supply inlet. The more efficient ionization may prevent or reduce contamination of the ion source caused by non-ionized source gas. The uniformity of the ion beam may be improved by increasing the density of ions in the ion beam. Additionally, an ion implanter including the ion source may have improved source gas ionization efficiency.

Furthermore, a throughput of an ion implantation process may be enhanced when the ion source according to embodiments of the present invention is employed for the ion implantation process. For example, a processing time of the ion implantation process may be reduced from about 3,990 seconds to about 2,990 seconds.

According to some embodiments, the energetic ions emitted from the electron emitting device are confined by a magnetic field (e.g., provided by an external magnetic field generator) to a path oscillating between the electron emitting device and the electron returning device.

According to some embodiments, the ion source is a Bernas-type ion source.

According to some embodiments, the arc chamber 103 is maintained under vacuum during the ionization process.

The foregoing is illustrative of the present invention and is not to be construed as limiting thereof. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

What is claimed is:

1. An ion source for ionizing a source gas, the ion source comprising:
an arc chamber housing defining an arc chamber to receive the source gas, the arc chamber having a first region and a second region;
an electron emitting device disposed in the arc chamber adjacent the first region and adapted to emit electrons into the first and the second regions to ionize the source gas;
an electron returning device disposed in the arc chamber adjacent the second region and adapted to return at least some of the electrons emitted from the electron emitting device into the second region; and
a gas supply system adapted to direct the source gas into the first region and into the second region.

2. The ion source of claim 1, wherein the gas supply system is adapted to provide a greater mass flow rate of the source gas into the first and second regions than is provided into other regions of the arc chamber.

3. The ion source of claim 2, wherein the gas supply system is adapted to provide a greater mass flow rate of the source gas into the first and second regions than is provided into a third region of the arc chamber located between the electron emitting device and the electron returning device and between the first and second regions.

4. The ion source of claim 1, wherein the gas supply system includes first and second gas supply inlets and is adapted to direct a first flow of the source gas from the first gas supply inlet to the first region along a first substantially direct flow path and is adapted to direct a second flow of the source gas from the second gas supply inlet to the second region along a second substantially direct flow path.

5. The ion source of claim 1, wherein:
the electron emitting device and the electron returning device are spaced apart along an axis;
the first and second regions are spaced apart along the axis and disposed between the electron emitting device and the electron returning device;
the gas supply system includes first and second gas supply inlets spaced apart along the axis; and
the first gas supply inlet is adapted to direct the source gas into the first region and the second gas supply inlet is adapted to direct the source gas into the second region.

6. The ion source of claim 1, wherein the gas supply system comprises a first gas supply inlet and a second gas supply inlet disposed in a sidewall of the arc chamber housing, wherein the first gas supply inlet and the second gas supply inlet are adapted to direct the source gas into the first region and the second region, respectively.

7. The ion source of claim 6, wherein the gas supply system comprises:
a gas source including a supply of the source gas;
a first line connected to the gas source; and
a pair of second lines divided from the first line and connected to the first and the second gas supply inlets, respectively.

8. The ion source of claim 7, wherein the gas supply system further comprises a gate valve and a mass flow controller installed in the first line.

9. The ion source of claim 7, wherein the gas supply system further comprises:
a gate valve installed in the first line; and
mass flow controllers installed in each of the second lines.

10. The ion source of claim 6, wherein each of the first and the second gas supply inlets has a diameter of from about 3 to 5 mm.

11. The ion source of claim 6, wherein a distance between a central portion of the first gas supply inlet and the electron emitting device is in the range of from about 5 to 15 mm.

12. The ion source of claim 6, wherein a distance between a central portion of the second gas supply inlet and the electron returning device is in the range of from about 5 to 15 mm.

13. The ion source of claim 6, wherein the gas supply system comprises;
a gas source including a supply of the source gas:
a first line connecting the gas source to the first gas supply inlet to provide the source gas to the first region; and
a second line connecting the gas source to the second gas supply inlet to provide the source gas to the second region.

14. The ion source of claim 13, wherein the gas supply system further comprises:
a first gate valve and a first mass flow controller installed in the first line; and
a second gate valve and a second mass flow controller installed in the second line.

15. The ion source of claim 1, wherein the ion source is adapted to direct the source gas into the first region at a first flow rate and into the second region at a second flow rate, and the first flow rate is equal to or larger than the second flow rate.

16. The ion source of claim 1, further comprising first and second gas injectors coupled to the first and the second gas supply inlets, respectively, to inject the source gas into the first and second regions, the gas injectors being located adjacent to the first and the second regions, respectively.

17. The ion source of claim 16, wherein each of the first and second gas injectors comprises a plurality of gas injection holes adapted to spray the source gas.

18. The ion source of claim 1, wherein the electron emitting device comprises a filament electrically connected to a filament power source, the filament extending into the arc chamber through a sidewall of the arc chamber housing.

19. The ion source of claim 18, further comprising a first insulation member disposed between the filament and the sidewall of the arc chamber.

20. The ion source of claim 1, wherein the electron emitting device member comprises:
a tube extending into the arc chamber through a sidewall of the arc chamber housing;
a cathode cap connected to an end portion of the tube; and
a filament disposed in the tube, the filament being electrically connected to a filament power source.

21. The ion source of claim 20, further comprising a second insulation member disposed between the tube and the sidewall of the arc chamber housing.

22. The ion source of claim 1, wherein the electron returning device comprises a reflector electrically connected to a negative potential.

23. The ion source of claim 1, wherein the electron returning device comprises an electrically floated repeller.

24. An ion implanter for implanting a material into a substrate, the ion implanter comprising:
an ion source adapted to ionize a source gas containing the material to be implanted into the substrate;
an end station unit adapted to handle the substrate to implant ions provided from the ion source; and
a transferring unit connecting the ion source to the end station unit to transfer the ions from the ion source to the end station unit;
wherein the ion source comprises:
an arc chamber housing defining an arc chamber to receive the source gas, the arc chamber having a first region and a second region;
an electron emitting device disposed in the arc chamber adjacent the first region and adapted to emit electrons into the first and second regions to ionize the source gas;
an electron returning device disposed in the arc chamber adjacent the second region and adapted to return at least some of the electrons emitted from the electron emitting device into the second region; and
a gas supply system adapted to direct the source gas into the first region and into the second region.

25. The ion implanter of claim 24, wherein the gas supply system is adapted to provide a greater mass flow rate of the source gas into the first and second regions than is provided into other regions of the arc chamber.

26. The ion implanter of claim 24, wherein the end station unit comprises:
a chuck adapted to support the substrate; and
a driving member adapted to tilt the chuck to adjust an incident angle of an ion beam including the ions and to move the chuck to scan a surface of the substrate supported by the chuck.

27. The ion implanter of claim 24, wherein the transferring unit comprises:
an ion extractor adapted to extract the ions from the ion source to form a first ion beam;
an analyzer magnet adapted to select ions to be implanted into the substrate; and
an accelerator adapted to accelerate a second ion beam including the ions selected by the analyzer magnet having a desired energy level.

28. The ion implanter of claim 24, wherein the gas supply system comprises a first gas supply inlet and a second gas supply inlet disposed in a sidewall of the arc chamber housing, wherein the first gas supply inlet and the second gas supply inlet are adapted to direct the source gas into the first region and the second region, respectively.

29. The ion implanter of claim 28, wherein the gas supply unit further comprises:
a gas storage including a supply of the source gas;
a first line connected to the gas source; and
a pair of second lines divided from the first line and connected to the first and the second gas supply inlets, respectively.

30. The ion implanter of claim 24, wherein the ion source is adapted to direct the source gas into the first region at a first flow rate and into the second region at a second flow rate, and the first flow rate is equal to or larger than the second flow rate.

31. The ion implanter of claim 24, further comprising first and second gas injectors coupled to the first and the second gas supply inlets, respectively, to inject the source gas into the first and second regions, the gas injectors being located adjacent to the first and the second regions, respectively.

32. The ion implanter of claim 24, wherein the electron emitting device comprises a filament electrically connected to a filament power source, the filament extending into the arc chamber through a sidewall of the arc chamber housing.

33. The ion implanter of claim 24, wherein the electron emitting device comprises:
a tube extending into the arc chamber housing;
a cathode cap connected to an end portion of the tube; and
a filament disposed in the tube and electrically connected to a filament power source.

34. The ion implanter of claim 24, wherein the electron returning device comprises a reflector electrically connected to a negative potential.

35. The ion implanter of claim 24, wherein the electron returning device comprises an electrically floated repeller.

36. A method for ionizing a source gas, the method comprising:
directing the source gas into a first region of an arc chamber and into a second region of the arc chamber;
emitting electrons from an electron emitting device into the first and the second regions to ionize the source gas, wherein the electron emitting device is disposed in the arc chamber adjacent the first region; and
returning at least some of the electrons emitted from the electron emitting device into the second region using an electron returning device, wherein the electron returning device is disposed in the arc chamber adjacent the second region.

37. The method of claim 36, wherein directing the source gas into the first region and into the second region includes providing a greater mass flow rate of the source gas into the first and second regions than is provided into a third region of the arc chamber located between the electron emitting device and the electron returning device and between the first and second regions.
